(19) United States
(12) Patent Application Publication
(10) Pub. No.: US 2009/0078950 A1
(43) Pub. Date: Mar. 26, 2009

(54) Package structure with replaceable element for light emitting diode

(76) Inventor: Tsung-Ting Sun, Chung-Ho City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/902,370

(22) Filed: Sep. 21, 2007

(51) Int. Cl. H01L 33/00

(52) U.S. Cl. 257/98; 257/E33.058

(57) ABSTRACT

A package structure for an LED is disclosed. The structure includes a first substrate, an LED chip, a second substrate, a protection layer and a replaceable optical element. The LED chip is disposed on the first substrate. The second substrate is disposed on the first substrate, and surrounds the LED chip. The second substrate has a first thread. The protection layer covers the LED chip. The replaceable optical element has a second thread, and is fastened to the second substrate through the first thread. An interior wall of the optical element corresponds to a surface of the protection layer in arc shape.

### FIELD OF THE INVENTION

The present invention generally relates to a package structure for a light emitting diode (LED), and more specifically relates to a technical field that changes light extraction pattern of the LED by using replaceable optical elements.

### BACKGROUND OF THE INVENTION

LED is a solid semiconductor element that releases energy as light when current is passed through it to enable two carriers combining, and has advantages of slight weight, short response time and non-pollution. With these advantages, LEDs can be applied in many industries. The high-power LEDs are developed to overcome insufficient brightness, so the LEDs can be taken as a light source and have gradually taken the place of traditional tungsten lamps.

A conventional LED structure 1 is shown in FIG. 1. The structure 1 uses a substrate 10 as a main body. A plurality of electrode pins 101 are arranged in the substrate 10. The electrode pins are extended to the outside from the inside of the substrate 10. A heat dissipation base 11 is disposed under the substrate 10. The head dissipation base 11 has a reflective hole 111 for accommodating an LED dice 12. The LED dice 12 contacts with a thermal conducting plate 13, and is surrounded by a plastic ring 102 disposed in the substrate 10. The LED dice 12 is electrically connected to the pins 101 through a wire. When the LED operates, heat generated by the LED is conducted by the thermal conducting plate 13 under the dice 12, so heat dissipation can be completed by the heat dissipation base 11. Simultaneously, the plastic ring 102 is employed to isolate the electrode circuit and a heat conducting path to prevent heat generated by the LED dice 12 from being conducted by the electrode circuit, thereby generating higher heat resistance. The LED dice 12 may not operate at normal working temperatures under high heat resistance. Light generated by the LED dice 12 is emitted through a lens 103 disposed on the substrate 10.

The aforesaid substrate 10 of the LED can overcome heat dissipation problem. Various light extraction characteristics or light patterns are required because the LED is in widespread use. Therefore, after the conventional LED is packaged completely, the lens 103 is fastened to the substrate 10. To get various light patterns, user must prepare many LEDs with different lenses or increase additional optical elements, thus resulting in time consuming.

To overcome the foregoing shortcomings, the inventor(s) of the present invention based on years of experience in the related field to conduct extensive researches and experiments, and finally invented a package structure with a replaceable element for an LED, as a method or a basis for resolving the foregoing drawbacks.

### SUMMARY OF THE INVENTION

Briefly, it is a primary object of the present invention to provide a package structure for an LED to change light shape of the LED by using a replaceable optical element, thereby enhancing convenience in usage.

To achieve the foregoing object, the package structure for the LED includes a first substrate, an LED chip, a second substrate, a protection layer and a replaceable optical element. The LED is disposed on the first substrate. The second substrate is disposed on the first substrate, and surrounds the LED chip, and has a first thread. The protection layer covers the LED chip. The replaceable optical element has a second thread, and is fastened to the second substrate through the first thread. An interior wall of the optical element corresponds to a surface of the protection layer in arc shape.

Moreover, the present invention further discloses a lens holder for accommodating the optical element to provide another embodiment of the replaceable optical element. According to the package structure for the LED, the light extraction pattern of the LED can change by replacing the optical element through the structural design with the replaceable optical element.

To make it easier for our examiner to understand the object of the invention, its innovative features and performance, a detailed description and technical characteristics of the present invention are described together with the drawings as follows.

### BRIEF DESCRIPTION OF THE DRAWINGS

FIG. 1 is an exploded assembly drawing of a conventional high-power LED;

FIG. 2 is an exploded assembly drawing of a package structure for an LED according to a first embodiment of the invention;

FIG. 3 is a perspective view of a package structure for an LED according to a first embodiment of the invention;

FIG. 4 is a cross-sectional drawing a package structure for an LED according to a first embodiment of the invention;

FIG. 5 is an exploded assembly drawing of a package structure for an LED according to a second embodiment of the invention;

FIG. 6 is a perspective view of a package structure for an LED according to a second embodiment of the invention;

FIG. 7 is an exploded assembly drawing of a package structure for an LED according to a third embodiment of the invention;

FIG. 8 is a perspective view of a package structure for an LED according to a third embodiment of the invention;

FIG. 9 is an exploded assembly drawing of a package structure for an LED according to a fourth embodiment of the invention;

FIG. 10 is a perspective view of a package structure for an LED according to a fourth embodiment of the invention;

FIG. 11 an exploded assembly drawing of a package structure for an LED according to a fifth embodiment of the invention; and

FIG. 12 is a perspective view of a package structure for an LED according to a fifth embodiment of the invention.

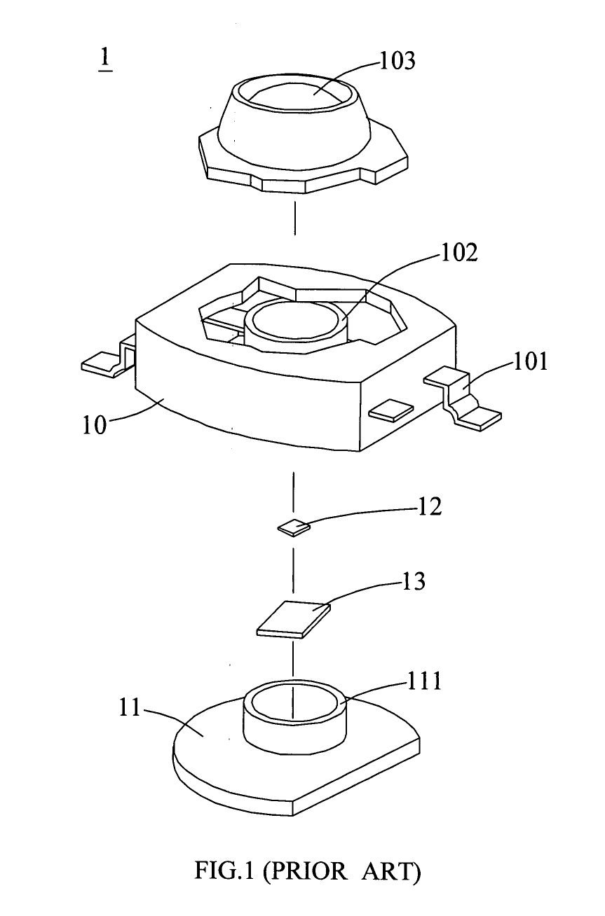

### DETAILED DESCRIPTION OF THE PREFERRED EMBODIMENTS

In the related figures for the package structure for an LED according to a preferred embodiment of the present invention, the same elements are described by the same reference numerals.

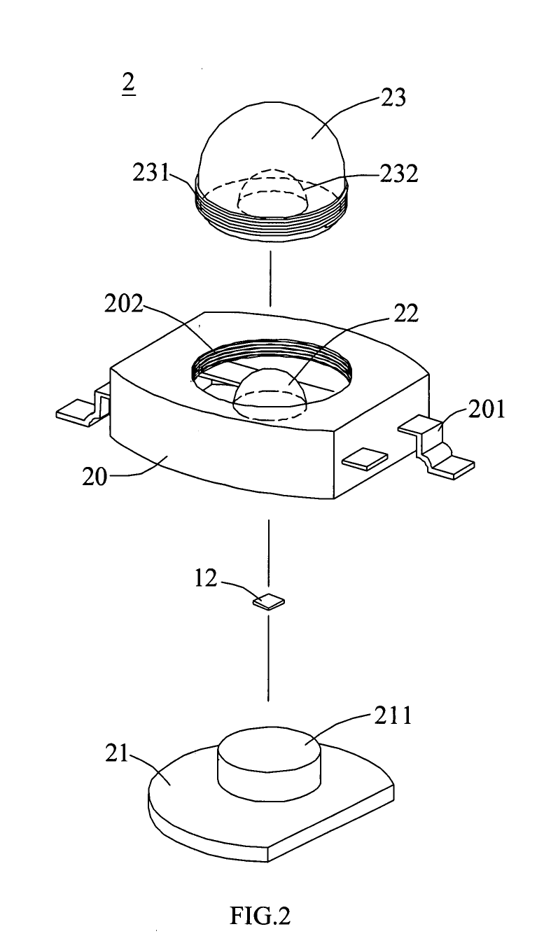

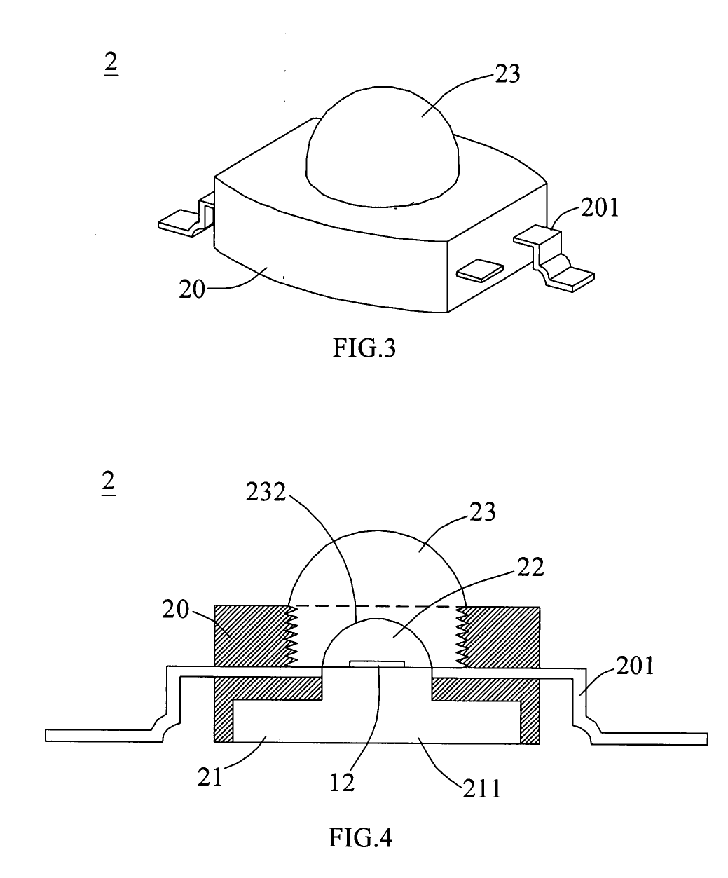

Referring to FIGS. 2, 3 and 4 for the exploded assembly drawing, the perspective drawing and the cross-sectional drawing illustrate a package structure for an LED in accordance with the present invention. The package structure 2 for the LED includes a first substrate 21, an LED chip 12, a second substrate 20, a protection layer 22 and a replaceable optical element 23.

The first substrate 21 has a first surface 211, and the material of the first substrate 21 includes a high thermal conducting material. The LED chip 12 is disposed on the first surface 211 of the first substrate 21. The LED chip 12 is covered by the protection layer 22, and the material of the protection layer 22 is silicone or epoxy resin.

The second substrate 20 is disposed on the first substrate 21, and surrounds the LED chip 12, and has a first thread 202 and electrode pins 201. The electrode pins 201 are used to receive an electrical signal to drive the LED chip 12 for emitting light. The second substrate 20 has high reflective capability upon demands. In general, a reflective surface is formed on a surface of the second substrate 20, and the first substrate 21 and the second substrate 20 may be made by integrated molding.

The replaceable optical element 23 has a second thread 231, and is fastened to the second substrate 20 through the first thread 20. An interior wall 232 of the optical element 23 corresponds to the surface of the protection layer 22 in arc shape. For example, the normal direction of the interior wall 232 of the optical element 23 is similar to the normal direction of the surface of the protection layer 22. Therefore, the light emitted by the LED chip 12 cannot be easily reflected by the interior wall 232 of the optical element 23 or the surface of the protection layer 22. The interior wall 232 of the optical element 23 may contact with the surface of the protection layer 22 or there is an interval between the interior wall 232 of the optical element 23 and the surface of the protection layer 22. The optical element 23 is generally a lens. The optical element 23 illustrated in the first embodiment is a Lambertian lens (as a lens for generating positive light).

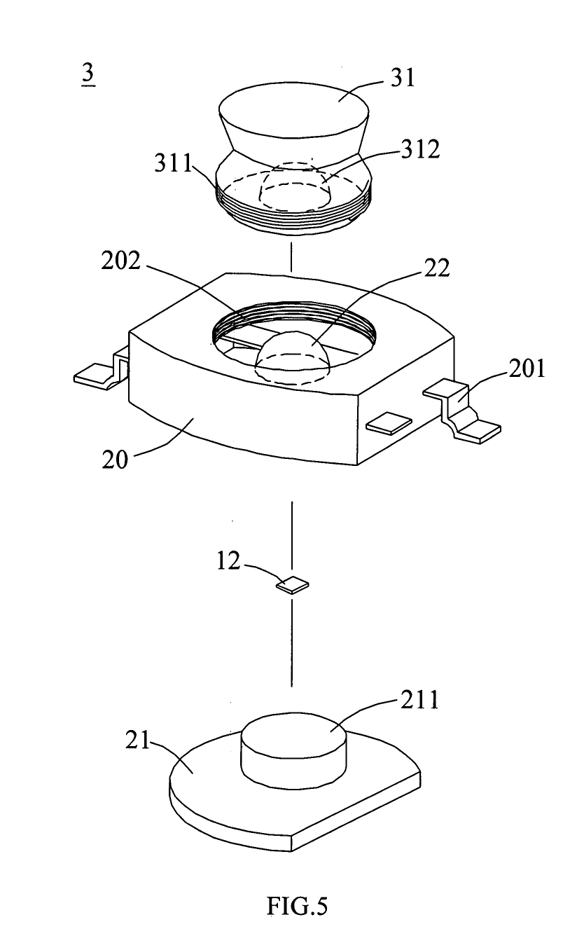

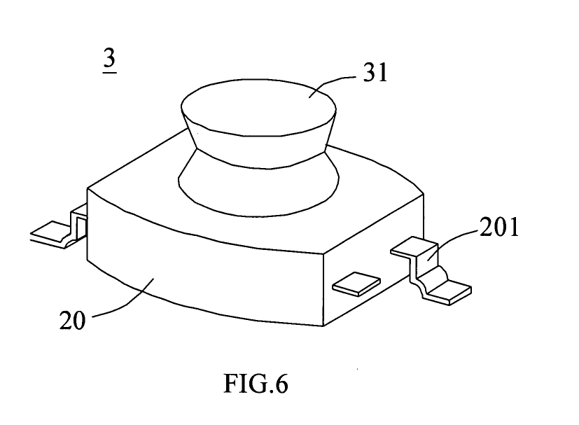

Referring to FIGS. 5 and 6 for the exploded assembly drawing and the perspective drawing illustrate a package structure for an LED according to a second embodiment in accordance with the invention. The package structure 3 for the LED differs from the package structure 2 for the LED because replaceable optical element 31 is a lens for generating side light extraction pattern. When user needs an LED having side light extraction pattern, he/she only needs to replace the optical element 23 with the optical element 31. The user can get side light extraction pattern by using the same LED chip 12. Moreover, the optical element 23 and the optical element 31 can be fastened to the second substrate 20 through threads to increase convenience.

In accordance with the package structure for the LED, the goal of conveniently replacing the optical element can be achieved through the design of threads to overcome the drawbacks of inconveniently using the conventional LED and increasing additional optical elements.

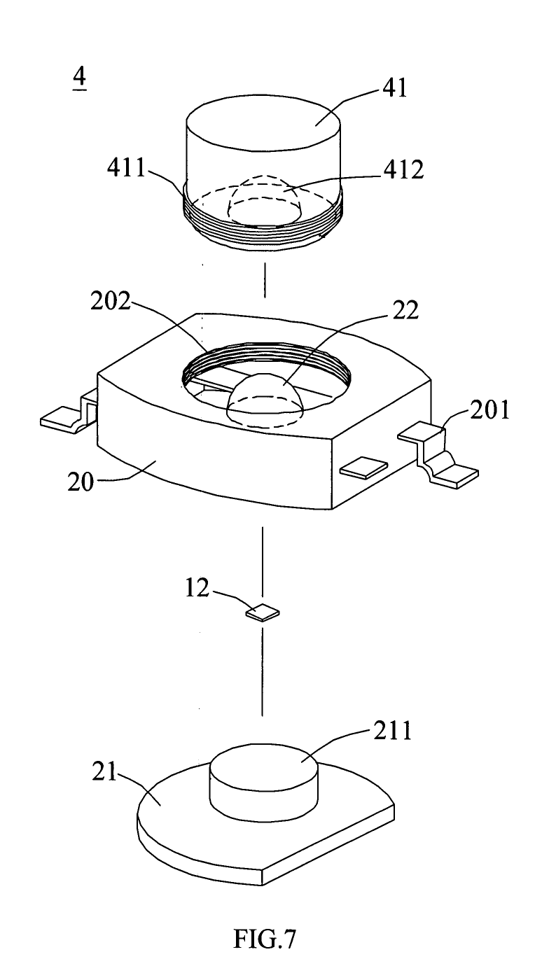

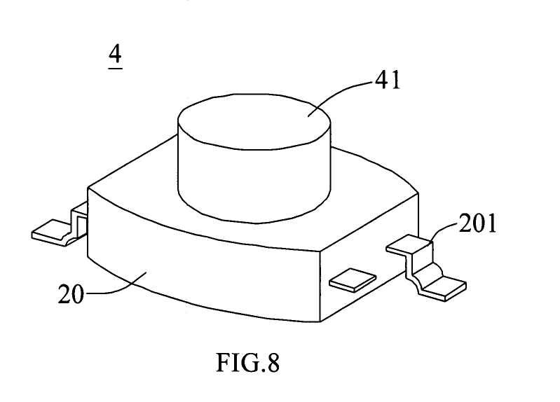

Referring to FIGS. 7 and 8 for the exploded assembly drawing and the perspective drawing illustrate a package structure for an LED according to a third embodiment in accordance with the invention. The package structure 4 for the LED differs from the package structure 3 for the LED and the package structure 2 for the LED because a replaceable optical element 41 illustrated herein is a lens with a cylinder shape that generates specific-angle light. When user needs an LED having specific-angle light extraction pattern, he/she only needs to replace the foregoing optical element with the optical element 41. The user can get specific-angle light extraction pattern by using the same LED chip 12. Moreover, the optical elements 23, 31 and 41 can be fastened to the second substrate 20 through threads to increase convenience.

In accordance with the package structure for the LED, the goal of conveniently replacing the optical element can be achieved through the design of threads to overcome the drawbacks of inconveniently using the conventional LED and increasing additional optical elements.

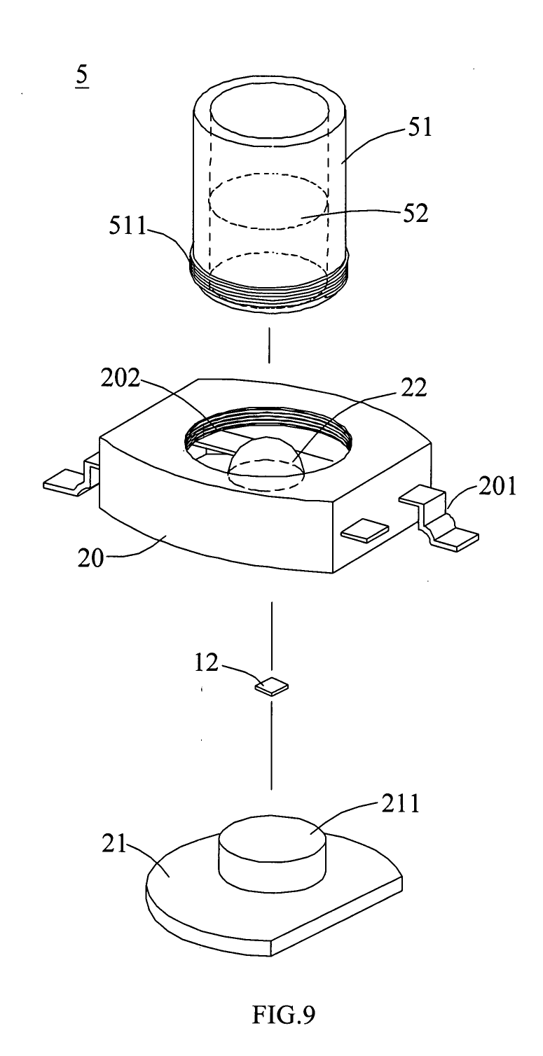

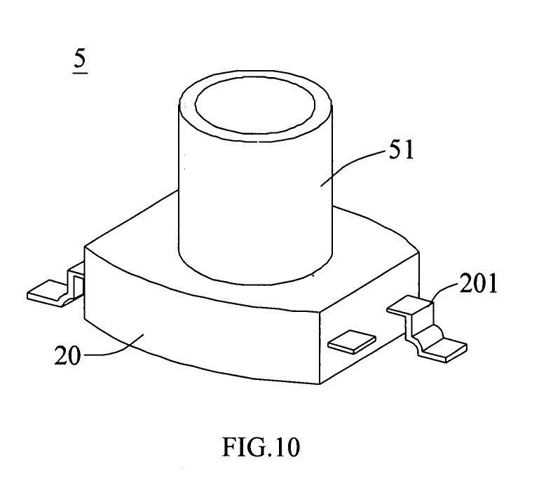

Referring to FIGS. 9 and 10 for the exploded assembly drawing and the perspective drawing illustrate a package structure for an LED according to a fourth embodiment in accordance with the invention. The package structure 5 for the LED includes the first substrate 21, the LED chip 12, the second substrate 20, the protection layer 22, a lens holder 51 and an optical element 52.

The first substrate 21 has a first surface 211, and the material of the first substrate 21 may be a high thermal conducting material. The LED chip 12 is disposed on the first surface 211 of the first substrate 21. The LED chip 12 is covered by the protection layer 22. The material of the protection layer 22 includes silicone or epoxy resin.

The second substrate 20 is disposed on the first substrate 21, and surrounds the LED chip 12. The second substrate 20 has a first thread 202 and electrode pins 201. The electrode pins 201 are used to receive an electrical signal to drive the LED chip 12 for emitting light. The second substrate 20 can have high reflective capability upon demands. In general, a reflective surface is formed on a surface of the second substrate 20. The first substrate 21 and the second substrate 20 may be made by integrated molding.

The lens holder 51 has an accommodating space and a second thread 511, and is fastened to the second substrate 20 through the first thread 202. The lens holder 51 is generally a hollow cylinder, and the interior wall of the lens holder 51 can form a reflective surface upon demands. The optical element 52 is disposed in the accommodating space of the lens holder 51. The optical element illustrated herein is generally a lens or a polarizer. The lens also includes a concave lens or a convex lens.

Therefore, in accordance with the package structure 5 for the LED of the fourth embodiment, the goal of conveniently replacing the optical element can be achieved through the design of threads to overcome the drawbacks of inconveniently using the conventional LED and increasing additional optical elements.

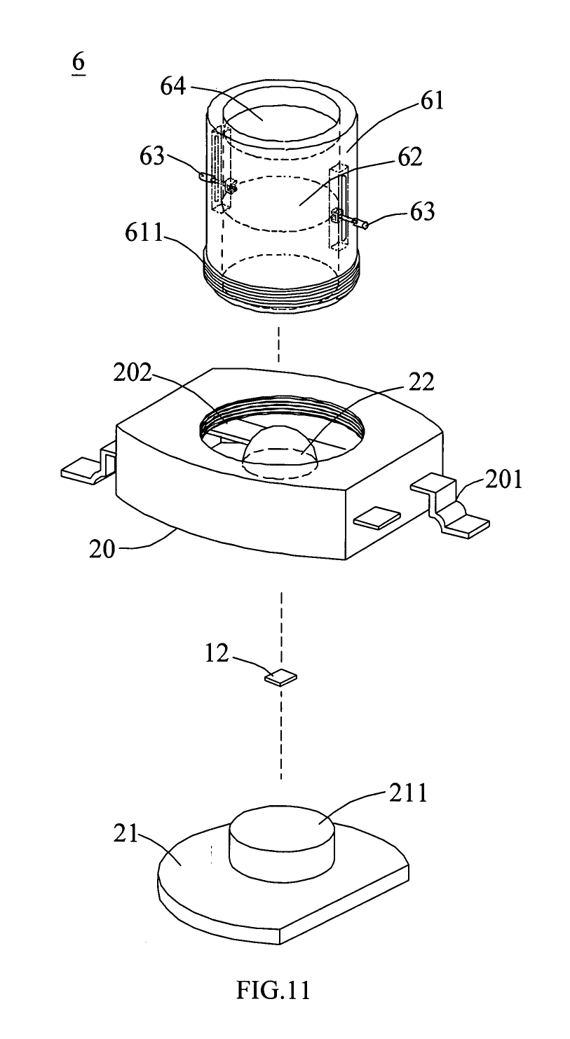

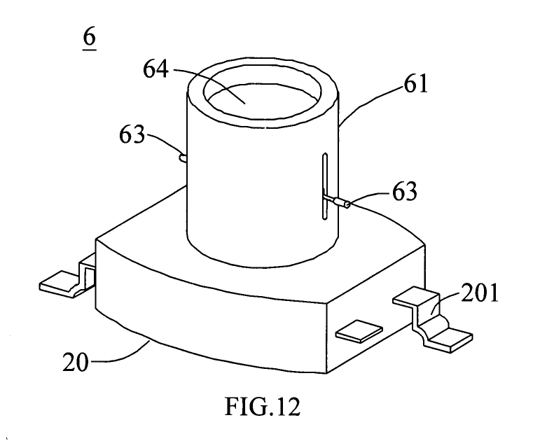

Referring to FIGS. 11 and 12 for the exploded assembly drawing and the perspective drawing illustrate a package structure for an LED according to a fifth embodiment of the invention. The package structure 6 for the LED includes the first substrate 21, the LED chip 12, the second substrate 20, the protection layer 22, a lens holder 61, an adjustment mechanism 63 and optical elements 62 and 64.

The first substrate 21 has a first surface 211, and the material of the first substrate 21 is a high thermal conducting material. The LED chip 12 is disposed on the first surface 211 of the first substrate 21. The LED chip 12 is covered by the protection layer 22. The material of the protection layer 22 includes silicone or epoxy resin.

The second substrate 20 is disposed on the first substrate 21, and surrounds the LED chip 12. The second substrate 20 has a first thread 202 and electrode pins 201. The electrode pins 201 are used to receive an electrical signal to drive the LED chip 12 for emitting light. The second substrate 20 can have high reflective capability upon demands. Namely, a reflective surface is formed on a surface of the second substrate 20. The first substrate 21 and the second substrate 20 may be made by integrated molding.

The lens holder 61 has an accommodating space and a second thread 611, and is fastened to the second substrate 20 through the first thread 202. The lens holder 61 is generally a hollow cylinder, and the interior wall of the lens holder 61 can form a reflective surface upon demands. The lens holder 61 has the adjustment mechanism 63 for adjusting the position of the optical element 62.

The optical elements 62 and 64 are disposed in the accommodating space of the lens holder 61. The optical elements illustrated herein are generally a lens or a polarizer. The lens also includes a concave lens or a convex lens. The position of the optical element 62 can be adjusted by the adjustment mechanism 63 for fine-tuning the position of light beam focusing.

Therefore, in accordance with the package structure 6 for the LED of the fifth embodiment, the goal of conveniently replacing the optical element can be achieved through the design of threads to overcome the drawbacks of inconveniently using the conventional LED and increasing additional optical elements. The user can replace appropriate optical elements based on the application area of the LED, and use the adjustment mechanism 63 to change the light extraction characteristic of the LED.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package structure for a light emitting diode (LED), comprising:
a first substrate;
an LED chip, disposed on the first substrate;
a second substrate, disposed on the first substrate and for surrounding the LED chip, and the second substrate has a first thread;
a protection layer, for covering the LED chip; and
a replaceable optical element, having a second thread, and fastened to the second substrate through the first thread, and an interior wall of the optical element corresponding to a surface of the protection layer in arc shape.

2. The package structure for the LED of claim 1, wherein the first substrate and the second substrate are made by integrated molding.

3. The package structure for the LED of claim 1, wherein the optical element is a lens.

4. The package structure for the LED of claim 1, wherein the second substrate has high reflective capability.

5. The package structure for the LED of claim 1, wherein a surface of the second substrate has a reflective surface.

6. The package structure for the LED of claim 1, wherein a normal of the interior wall of the optical element is similar to a normal of the surface of the protection layer.

7. The package structure for the LED of claim 1, wherein the interior wall of the optical element contacts with the surface of the protection layer or an interval is between the interior wall of the optical element and the surface of the protection layer.

8. The package structure for the LED of claim 1, wherein materials of the protection layer includes silicone or epoxy resin.

9. The package structure for the LED of claim 3, wherein the lens includes a Lambertian lens, a side light lens or a lens with specific-angle light.

10. The package structure for the LED of claim 1, wherein the first substrate is a high thermal conducting material.

11. A package structure for an LED, comprising:
a first substrate;
an LED chip, disposed on the first substrate;
a second substrate, disposed on the first substrate and surrounding the LED chip, the second substrate having a first thread;
a protection layer, for covering the LED chip;
a lens holder, having an accommodating space and a second thread, and fastened to the second substrate through the first thread; and
at least one optical element, disposed in the accommodating space of the lens holder.

12. The package structure for the LED of claim 11, wherein the first substrate and the second substrate are made by integrated molding.

13. The package structure for the LED of claim 11, wherein the optical element includes a lens or a polarizer.

14. The package structure for the LED of claim 13, wherein the lens includes a convex lens or a concave lens.

15. The package structure for the LED of claim 11, wherein the second substrate has high reflective capability.

16. The package structure for the LED of claim 11, wherein a surface of the second substrate has a reflective surface.

17. The package structure for the LED of claim 11, wherein the lens holder is a hollow cylinder.

18. The package structure for the LED of claim 11, wherein an interior wall of the lens holder has a reflective surface.

19. The package structure for the LED of claim 11, wherein the lens holder has an adjustment mechanism for adjusting a position of the optical element.

20. The package structure for the LED of claim 11, wherein the first substrate is a high thermal conducting material.
